(19) United States
(12) Patent Application Publication
(10) Pub. No.: US 2025/0072020 A1
(43) Pub. Date: Feb. 27, 2025

(54) SEMICONDUCTOR PACKAGE

(71) Applicant: ROHM Co., LTD., Kyoto (JP)

(72) Inventor: Akira Sagawa, Kyoto (JP)

(21) Appl. No.: 18/813,593

(22) Filed: Aug. 23, 2024

(30) Foreign Application Priority Data
Aug. 24, 2023 (JP) 2023-136011

(51) Int. Cl. H01L 29/872; H01L 23/00; H01L 29/20; H01L 29/24; H01L 29/417; H01L 29/47; H01L 29/868

(52) U.S. Cl. CPC H01L 29/872; H01L 29/2003; H01L 29/24; H01L 29/417; H01L 29/47; H01L 29/868; H01L 24/48; H01L 2224/48175; H01L 2924/12031; H01L 2924/12032

(57) ABSTRACT

Provided is a semiconductor package including a Si substrate, a drift layer, a buffer layer, an anode electrode, a trench, a semiconductor apparatus, an anode terminal, a cathode terminal, and a sealing resin.

### CROSS REFERENCE TO RELATED APPLICATIONS

This application claims priority benefit of Japanese Patent Application No. JP 2023-136011 filed in the Japan Patent Office on Aug. 24, 2023. Each of the above-referenced applications is hereby incorporated herein by reference in its entirety.

### BACKGROUND

The present disclosure relates to a semiconductor package.

A Schottky barrier diode containing gallium oxide (Ga₂O₃) is disclosed in Japanese Patent Laid-Open No. 2019-179815 (hereinafter, Patent Document 1). The Schottky barrier diode described in Patent Document 1 includes a semiconductor substrate containing gallium oxide, a drift layer containing gallium oxide and formed on the semiconductor substrate, an anode electrode that comes into Schottky contact with the drift layer, and a cathode electrode that comes into ohmic contact with the semiconductor substrate.

### BRIEF DESCRIPTION OF THE DRAWINGS

FIG. 1 is a graphic plan view for describing the configuration of a first semiconductor apparatus mounted on a semiconductor package according to the present embodiment;

FIG. 2 is a graphic cross-sectional view taken along line II-II in FIG. 1;

FIG. 3 is a schematic plan view of the semiconductor package provided with the first semiconductor apparatus;

FIG. 4 is a cross-sectional view taken along line IV-IV in FIG. 3;

FIG. 5 is a schematic plan view illustrating another example of the semiconductor package provided with the first semiconductor apparatus;

FIG. 6 is a cross-sectional view taken along line VI-VI in FIG. 5;

FIG. 7 is a graphic plan view for describing the configuration of a second semiconductor apparatus mounted on a semiconductor package according to the present embodiment;

FIG. 8 is a graphic cross-sectional view taken along line VIII-VIII in FIG. 7;

FIG. 9 is a schematic plan view of the semiconductor package provided with the second semiconductor apparatus;

FIG. 10 is a cross-sectional view taken along line X-X in FIG. 9;

FIG. 11 is a schematic plan view illustrating another example of the semiconductor package provided with the second semiconductor apparatus;

FIG. 12 is a cross-sectional view taken along line XII-XII in FIG. 11;

FIG. 13 is a graphic plan view for describing the configuration of a third semiconductor apparatus mounted on a semiconductor package according to the present embodiment;

FIG. 14 is a graphic cross-sectional view taken along line XIII-XIII in FIG. 13;

FIG. 15 is a schematic plan view of the semiconductor package provided with the third semiconductor apparatus;

FIG. 16 is a cross-sectional view taken along line XVI-XVI in FIG. 15;

FIG. 17 is a schematic plan view illustrating another example of the semiconductor package provided with the third semiconductor apparatus;

FIG. 18 is a cross-sectional view taken along line XVIII-XVIII in FIG. 17;

FIG. 19 is a graphic plan view for describing the configuration of a fourth semiconductor apparatus mounted on a semiconductor package according to the present embodiment;

FIG. 20 is a graphic cross-sectional view taken along line XX-XX in FIG. 19;

FIG. 21 is a schematic plan view of the semiconductor package provided with the fourth semiconductor apparatus;

FIG. 22 is a cross-sectional view taken along line XXII-XXII in FIG. 21;

FIG. 23 is a schematic plan view illustrating another example of the semiconductor package provided with the fourth semiconductor apparatus; and

FIG. 24 is a cross-sectional view taken along line XXIV-XXIV in FIG. 23.

### DETAILED DESCRIPTION

An embodiment of the present disclosure will be described in detail with reference to the attached drawings.

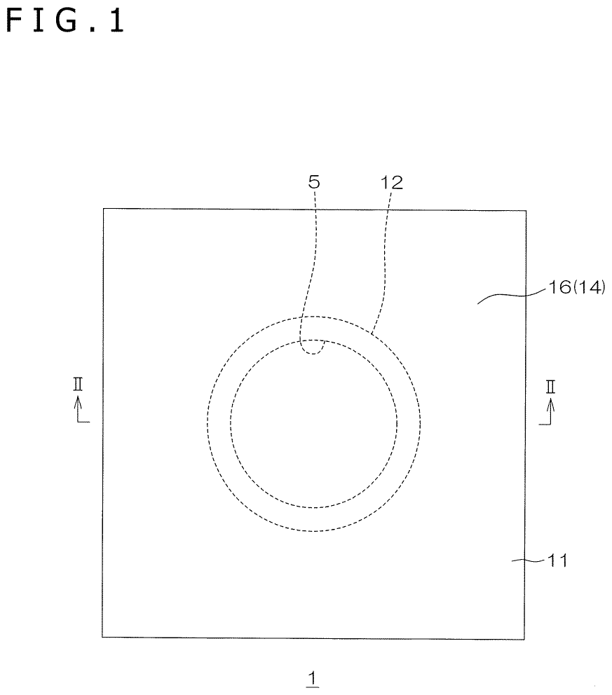

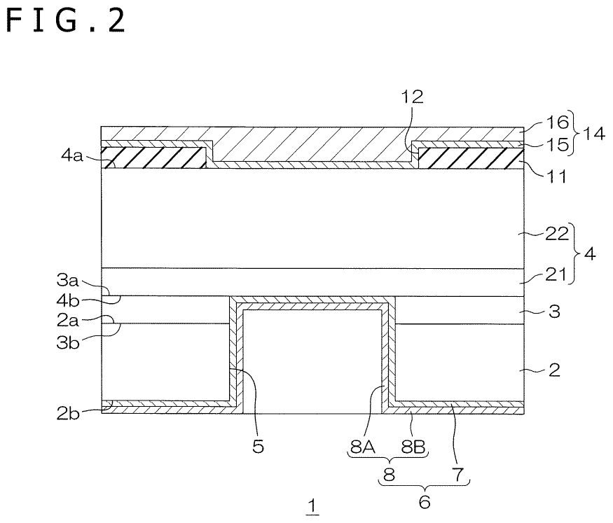

FIG. 1 is a graphic plan view for describing the configuration of a first semiconductor apparatus mounted on a semiconductor package according to the present embodiment. FIG. 2 is a graphic cross-sectional view taken along line II-II in FIG. 1.

A first semiconductor apparatus 1 is a Schottky barrier diode. The first semiconductor apparatus 1 is formed in, for example, a rectangular chip shape in plan view as illustrated in FIG. 1. The length of each of four sides of the first semiconductor apparatus 1 in plan view is, for example, approximately several mm. In the embodiment, the length of each of the four sides of the first semiconductor apparatus 1 in plan view is approximately 1 mm (1000 μm).

The first semiconductor apparatus 1 includes a Si (silicon) substrate 2 including a first main surface (front surface) 2a and a second main surface (back surface) 2b. The Si substrate 2 is rectangular in plan view. The first semiconductor apparatus 1 also includes a buffer layer 3 formed on the first main surface 2a of the Si substrate 2. The buffer layer 3 includes a first main surface (front surface) 3a and a second main surface (back surface) 3b. The buffer layer 3 has a rectangular shape in line with the Si substrate 2 in plan view.

The first semiconductor apparatus 1 further includes a drift layer 4 including a gallium semiconductor layer and formed on the first main surface 3a of the buffer layer 3. The drift layer 4 includes a first main surface (front surface) 4a and a second main surface (back surface) 4b. The drift layer 4 has a rectangular shape in line with the buffer layer 3 in plan view. The first main surface 4a of the drift layer 4 is an example of the “first surface of drift layer” in the present disclosure, and the second main surface 4b of the drift layer 4 is an example of the “second surface of drift layer” in the present disclosure.

The Si substrate 2 is doped with n-type impurities. Phosphorus (P), for example, is used as the n-type impurities. The n-type impurity concentration in the Si substrate 2 may be, for example, approximately 1×10¹⁶ cm⁻³ to 1×10²⁰ cm⁻³. The first main surface 2a and the second main surface 2b of the Si substrate 2 are (111) planes. The thickness of the Si substrate 2 is, for example, approximately 50 to 1000 μm. In the embodiment, the thickness of the Si substrate 2 is approximately 100 μm.

The buffer layer 3 in the embodiment contains aluminum nitride (AlN) having a crystal structure with in-plane six-fold symmetry. The first main surface 3a and the second main surface 3b of the buffer layer 3 containing aluminum nitride are (0001) planes. That is, a hexagonal material including (0001) planes as main surfaces is used as the buffer layer 3 in the embodiment. The thickness of the buffer layer 3 is, for example, approximately 100 to 200 nm. In the embodiment, the thickness of the buffer layer 3 is approximately 160 nm.

The reason that the buffer layer 3 is provided is as follows. If the drift layer 4 including the gallium semiconductor layer is directly formed on the Si substrate 2, a high-quality drift layer 4 cannot be obtained due to the eutectic reaction of the silicon of the Si substrate 2 and the gallium of the drift layer 4. Therefore, the buffer layer 3 is provided between the Si substrate 2 and the drift layer 4 to suppress the reaction (mixed crystal) of the silicon of the Si substrate 2 and the gallium oxide of the drift layer 4.

The drift layer 4 includes a gallium semiconductor layer. The gallium semiconductor layer includes a Ga₂O₃ semiconductor layer and a GaN semiconductor layer. The Ga₂O₃ semiconductor layer includes an (Inₓ₁Ga₍₁₋ₓ₁₎)₂O₃ layer, an (Alₓ₂Ga₍₁₋ₓ₂₎)₂O₃ layer, for example. The GaN semiconductor layer includes a Scₓ₃Ga₍₁₋ₓ₃₎N layer, a Tlₓ₄Ga₍₁₋ₓ₄₎N layer, an Alₓ₅Ga₁₋ₓ₅N layer, for example.

In the embodiment, the drift layer 4 includes a first drift layer 21 as a lower layer formed on the first main surface 3a of the buffer layer 3, and a second drift layer 22 as an upper layer laminated on the first drift layer 21.

In the embodiment, the first drift layer 21 includes a Ga₂O₃ semiconductor layer doped with n-type impurities. Examples of the Ga₂O₃ semiconductor layer include an (Inₓ₁Ga₁₋ₓ)₂O₃ (0≤x1<1) layer and an (Alₓ₂Ga₁₋ₓ₂)₂O₃ (0≤x2<1) layer.

In the embodiment, the first drift layer 21 includes a gallium oxide (Ga₂O₃) layer doped with n-type impurities. In the embodiment, the n-type impurities contain silicon (Si). The concentration of the n-type impurities is approximately 1×10¹⁸ cm⁻³ to 1×10²⁰ cm⁻³. In the embodiment, the concentration of the n-type impurities is approximately 1×10¹⁹ cm⁻³. The film thickness of the first drift layer 21 is approximately 200 nm. Note that the n-type impurities may contain tin (Sn).

The second drift layer 22 includes an undoped Ga₂O₃ semiconductor layer. In the specification, the undoped Ga₂O₃ semiconductor layer denotes a Ga₂O₃ semiconductor layer with the impurity concentration of smaller than 1×10¹⁶/cm³. Examples of the gallium oxide semiconductor layer include an (Inₓ₁Ga₁₋ₓ)₂O₃ (0≤x1<1) layer and (A1ₓ₂Ga₁₋ₓ₂)₂O₃ (0≤x2<1) layer. In the embodiment, the second drift layer 22 includes an undoped gallium oxide (Ga₂O₃) layer. The film thickness of the second drift layer 22 is approximately 6 μm.

Note that the drift layer 4 may include one gallium oxide (Ga₂O₃) layer doped with n-type impurities.

A laminated body of the Si substrate 2 and the buffer layer 3 is provided with one trench 5 formed by digging the laminated body from the center part of the second main surface 2b of the Si substrate 2 toward the second main surface 4b of the drift layer 4. The trench 5 penetrates the Si substrate 2 and the buffer layer 3 and reaches the second main surface 4b of the drift layer 4. The trench 5 is formed to reduce the resistivity from the first main surface 2a of the Si substrate 2 to the second main surface 2b of the Si substrate 2.

In the embodiment, the bottom surface of the trench 5 is formed by the second main surface 4b of the drift layer 4. In the embodiment, the shape of the cross section of the trench 5 is a circular shape. In the embodiment, the diameter of the trench 5 is approximately 380 μm.

An ohmic metal 7 that comes into ohmic contact with the second main surface 4b of the drift layer 4 is formed on the entire inner surfaces (bottom surface and side surface) of the trench 5 and the entire second main surface 2b of the Si substrate 2. The ohmic metal 7 contains metal (such as titanium (Ti) and indium (In)) that comes into ohmic contact with an n-type Ga₂O₃ semiconductor. In the embodiment, the ohmic metal 7 contains titanium (Ti). The thickness of the ohmic metal 7 is, for example, approximately 0.3 to 300 nm.

An electrode metal 8 is formed on the surface of the ohmic metal 7. The electrode metal 8 contains copper (Cu), gold (Au), for example. In the embodiment, the electrode metal 8 contains copper (Cu). The electrode metal 8 includes a first part 8A covering the surface of the ohmic metal 7 in the trench 5 and a second part 8B covering the surface of the ohmic metal 7 outside the trench 5. The second part 8B covers the entire second main surface 2b of the Si substrate 2.

Note that the electrode metal 8 may be completely embedded into the trench 5. In that case, the entire back surface of the electrode metal 8 may be flat.

The ohmic metal 7 and the electrode metal 8 form a cathode electrode 6. That is, the cathode electrode 6 in the embodiment has a multi-layer structure (two-layer structure in the embodiment) including the ohmic metal 7 connected to the Si substrate 2 and the electrode metal 8 laminated on the ohmic metal 7. In the embodiment, the electrode metal 8 is a part of the cathode electrode 6 exposed to the outermost surface of the first semiconductor apparatus 1 and connected to a bonding wire, for example.

The region corresponding to the bottom surface of the trench 5 in the second main surface 4b of the drift layer 4 is covered by the ohmic metal 7 of the cathode electrode 6. In other words, the region corresponding to the bottom surface of the trench 5 in the second main surface 4b of the drift layer 4 is in contact with the ohmic metal 7 (cathode electrode 6). The other region in the second main surface 4b of the drift layer 4 (region not provided with the trench 5 in plan view) is in contact with the first main surface 3a of the buffer layer 3.

A field insulating film 11 containing silicon nitride (SiN) is laminated on the first main surface 4a of the drift layer 4. The thickness of the field insulating film 11 is, for example, equal to or greater than 100 nm, preferably, approximately 700 to 4000 nm. The field insulating film 11 may contain another insulator such as silicon oxide (SiO₂).

An opening 12 for exposing the center part of the drift layer 4 is formed on the field insulating film 11. In the embodiment, the opening 12 is circular in plan view. In the embodiment, the diameter of the opening 12 is approximately 400 μm. An anode electrode 14 is formed on the field insulating film 11.

The anode electrode 14 fills up the opening 12 of the field insulating film 11 and projects outside the opening 12 like a flange so as to cover a periphery 13 of the opening 12 in the field insulating film 11. That is, the upper and lower sides of the periphery of the opening 12 in the field insulating film 11 are sandwiched by the drift layer 4 and the anode electrode 14. In the embodiment, the anode electrode 14 has a rectangular shape in line with the drift layer 4 in plan view. In the embodiment, the anode electrode 14 functions as a terminal for flip-chip bonding of the first semiconductor apparatus 1, and the anode electrode 14 may be referred to as an external terminal.

The anode electrode 14 in the embodiment has a multi-layer structure (two-layer structure in the embodiment) including a Schottky metal 15 connected to the drift layer 4 in the opening 12 of the field insulating film 11 and an electrode metal 16 laminated on the Schottky metal 15.

The Schottky metal 15 contains metal that forms a Schottky junction when the metal is connected to the Ga₂O₃ semiconductor. In the embodiment, the Schottky metal 15 contains nickel (Ni). The Schottky metal 15 connected to the drift layer 4 forms a Schottky barrier (potential barrier) between the Schottky metal 15 and the Ga₂O₃ semiconductor layer included in the drift layer 4. The thickness of the Schottky metal 15 is, for example, approximately 0.02 to 0.20 μm in the embodiment.

The electrode metal 16 contains copper (Cu), gold (Au), for example. In the embodiment, the electrode metal 16 contains copper (Cu). The thickness of the electrode metal 16 is larger than the thickness of the Schottky metal 15 and is, for example, approximately 0.5 to 5.0 μm in the embodiment.

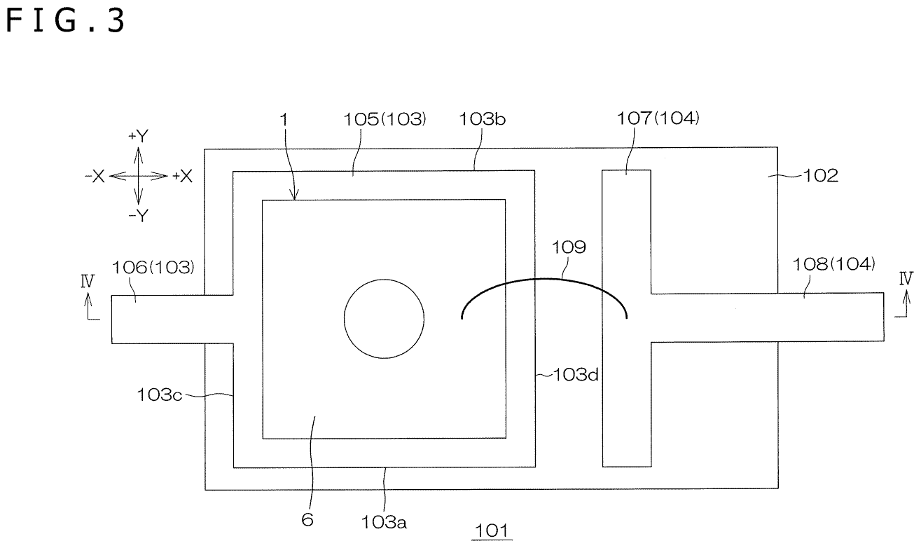

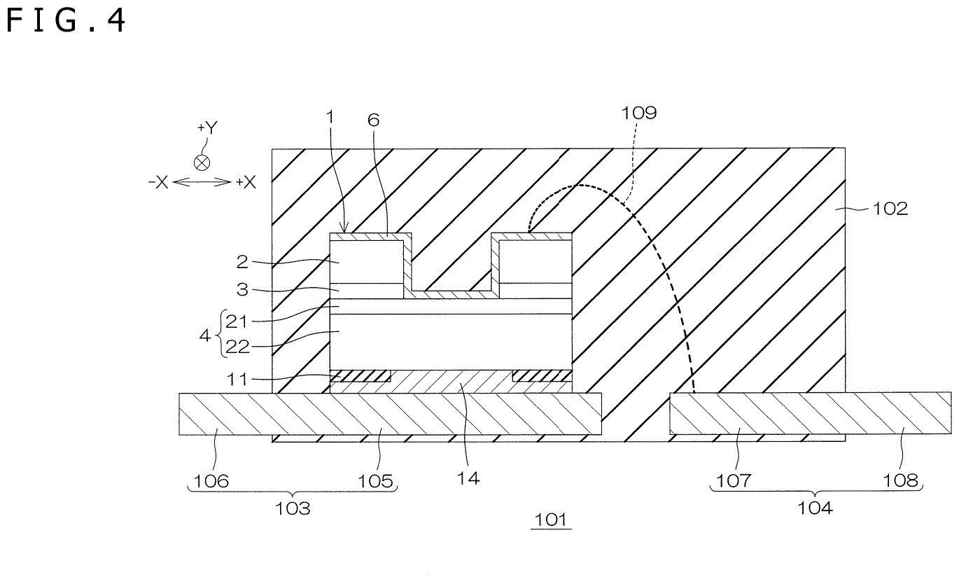

FIG. 3 is a schematic plan view of the semiconductor package provided with the first semiconductor apparatus 1. FIG. 4 is a cross-sectional view taken along line IV-IV in FIG. 3.

For the convenience of description, a +X direction, a −X direction, a +Y direction, and a −Y direction illustrated in FIGS. 3 and 4 may be used below. The +X direction is a predetermined direction along the main surfaces 2a and 2b of the Si substrate 2. The +Y direction is a predetermined direction along the main surfaces 2a and 2b of the Si substrate 2 and is a direction orthogonal to the +X direction.

The −X direction is a direction opposite the +X direction. The −Y direction is a direction opposite the +Y direction. The +X direction and the −X direction may collectively and simply be referred to as an “X direction.” The +Y direction and the −Y direction may collectively and simply be referred to as a “Y direction.”

In FIGS. 3 and 4, the first semiconductor apparatus 1 illustrated in FIGS. 1 and 2 is vertically inverted and arranged.

A semiconductor package 101 includes a resin package 102 in a cuboid shape and an anode terminal 103 and a cathode terminal 104 sealed in the resin package 102.

The two terminals 103 and 104 include metal plates formed in a predetermined shape. The anode terminal 103 includes an island 105 and a terminal part 106.

The island 105 has a rectangular shape including two sides 103a and 103b parallel to each other in the X direction and two sides 103c and 103d parallel to each other in the Y direction in plan view. The terminal part 106 extends in the −X direction from the center part of the length of the one side 103c of the island 105 and has a rectangular shape elongated in the X direction in plan view.

The cathode terminal 104 is arranged on the opposite side of the terminal part 106 with respect to the island 105. The cathode terminal 104 includes a wire connection 107 and a terminal part 108.

The wire connection 107 is arranged at an interval from the side 103d of the island 105 in the +X direction, and the wire connection 107 has a rectangular shape elongated in the Y direction in plan view. The terminal part 108 extends in the +X direction from the center part of the length of the wire connection 107 and has a rectangular shape elongated in the X direction in plan view.

The first semiconductor apparatus 1 is mounted on the center part of the island 105 of the anode terminal 103 through flip-chip bonding. Specifically, the first semiconductor apparatus 1 is vertically inverted, and the anode electrode 14 of the first semiconductor apparatus 1 is connected to the upper surface of the island 105.

The cathode electrode 6 of the first semiconductor apparatus 1 is connected to the wire connection 107 of the cathode terminal 104 through a bonding wire 109.

The first semiconductor apparatus 1, the island 105, the base end of the terminal part 106, the wire connection 107, the base end of the terminal part 108, and the bonding wire 109 are sealed in the resin package 102. The front end of the terminal part 106 protrudes in the −X direction from the end surface of the resin package 102 on the −X side. The front end of the terminal part 108 protrudes in the +X direction from the end surface of the resin package 102 on the +X side.

In the first semiconductor apparatus 1, heat is easily generated at the boundary of the anode electrode 14 and the first main surface 4a of the drift layer 4. In the semiconductor package 101, the anode electrode 14 is connected to the island 105 of the anode terminal 103, and the heat generated at the boundary of the anode electrode 14 and the first main surface 4a of the drift layer 4 can be easily released.

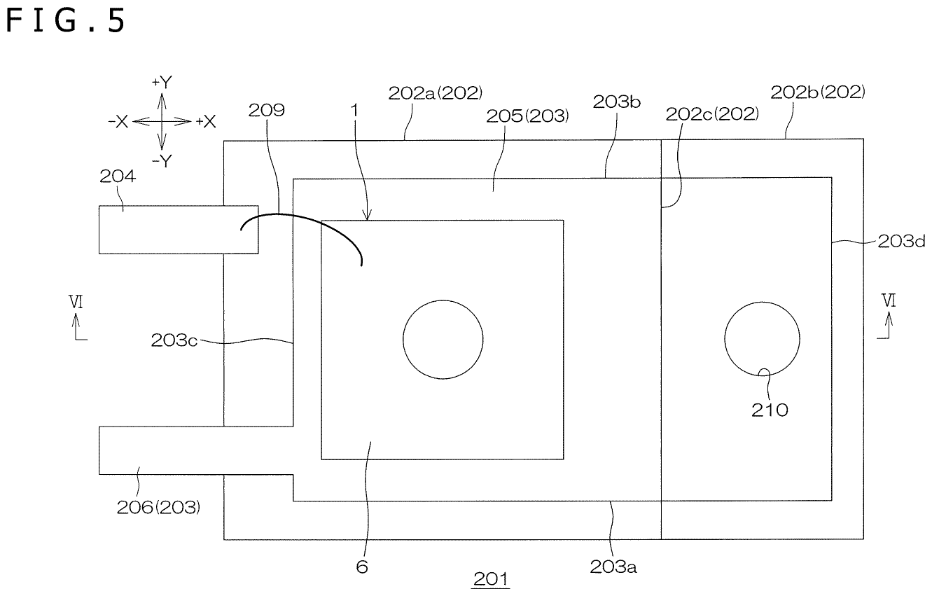

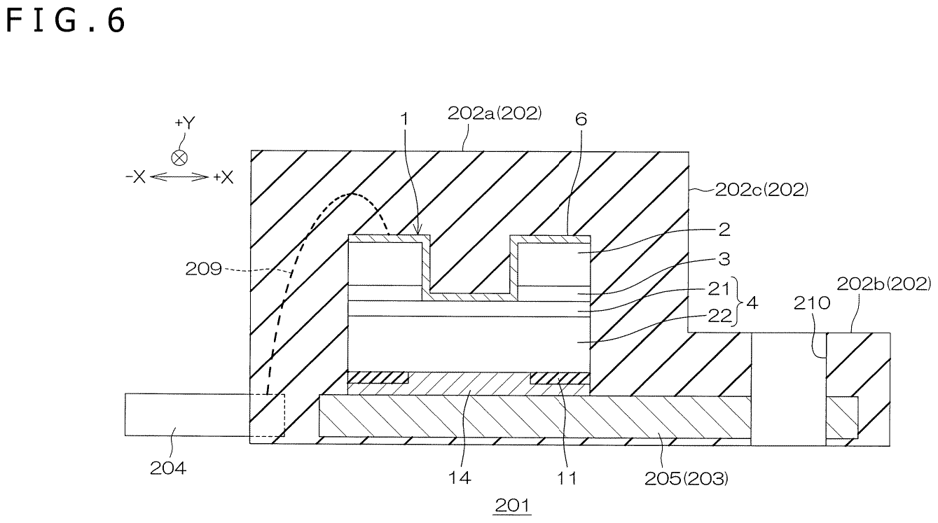

FIG. 5 is a schematic plan view illustrating another example of another semiconductor package provided with the first semiconductor apparatus 1. FIG. 6 is a cross-sectional view taken along line VI-VI in FIG. 5.

For the convenience of description, the +X direction, the −X direction, the +Y direction, and the −Y direction illustrated in FIGS. 5 and 6 may be used below. The +X direction is a predetermined direction along the main surfaces 2a and 2b of the substrate 2. The +Y direction is a predetermined direction along the main surfaces 2a and 2b of the substrate 2 and is a direction orthogonal to the +X direction.

The −X direction is a direction opposite the +X direction. The −Y direction is a direction opposite the +Y direction. The +X direction and the −X direction may collectively and simply be referred to as the “X direction.” The +Y direction and the −Y direction may collectively and simply be referred to as the “Y direction.”

In FIGS. 5 and 6, the first semiconductor apparatus 1 illustrated in FIGS. 1 and 2 is vertically inverted and arranged.

A semiconductor package 201 includes a resin package 202 in a rectangular shape in plan view, and an anode terminal 203 and a cathode terminal 204 sealed in the resin package 202.

The two terminals 203 and 204 include metal plates formed in a predetermined shape. The anode terminal 203 includes an island 205 and a terminal part 206. The island 205 has a rectangular shape including two sides 203a and 203b parallel to each other in the X direction and two sides 203c and 203d parallel to each other in the Y direction in plan view. The terminal part 206 linearly extends in the −X direction from the position closer to the −Y side end of the one side 203c of the island 205 and has a rectangular shape elongated in the X direction in plan view.

The cathode terminal 204 has a shape similar to the terminal part 206 of the anode terminal 203 in plan view, and the cathode terminal 204 is arranged at an interval from the terminal part 206 of the anode terminal 203 in the +Y direction. The +X side end of the cathode terminal 204 is arranged at an interval from the side 203c of the island 205 in the −X direction.

The first semiconductor apparatus 1 is mounted on the center part of the island 205 of the anode terminal 203 through flip-chip bonding. Specifically, the first semiconductor apparatus 1 is vertically inverted, and the anode electrode 14 of the first semiconductor apparatus 1 is connected to the upper surface of the island 205.

The cathode electrode 6 of the first semiconductor apparatus 1 is connected to the +X side part of the cathode terminal 204 in the length direction through a bonding wire 209.

The resin package 202 includes a main portion 202a in a cuboid shape, and a thin portion 202b arranged on the +X side of the main portion 202a and thinner than the main portion 202a. The bottom surface of the main portion 202a and the bottom surface of the thin portion 202b are flush with each other. A step portion 202c is formed between the upper surface of the thin portion 202b and the upper surface of the main portion 202a.

The main portion 202a seals the first semiconductor apparatus 1, the part of the island 205 excluding the +X direction end, the base end of the terminal part 206, the +X side part of the cathode terminal 204 in the length direction, and the bonding wire 209. The thin portion 202b seals the +X direction end of the island 205.

The front end of the terminal part 206 protrudes in the −X direction from the end surface of the main portion 202a on the −X side. The −X side part of the cathode terminal 204 in the length direction protrudes in the −X direction from the end surface of the main portion 202a on the −X side.

A through hole 210 penetrating the thin portion 202b and the +X side end of the island 205 in the vertical direction is formed near the center of the thin portion 202b in plan view.

In the first semiconductor apparatus 1, heat is easily generated at the boundary of the anode electrode 14 and the first main surface 4a of the drift layer 4. In the semiconductor package 201, the anode electrode 14 is connected to the island 205 of the anode terminal 203, and the heat generated at the boundary of the anode electrode 14 and the first main surface 4a of the drift layer 4 can be easily released.

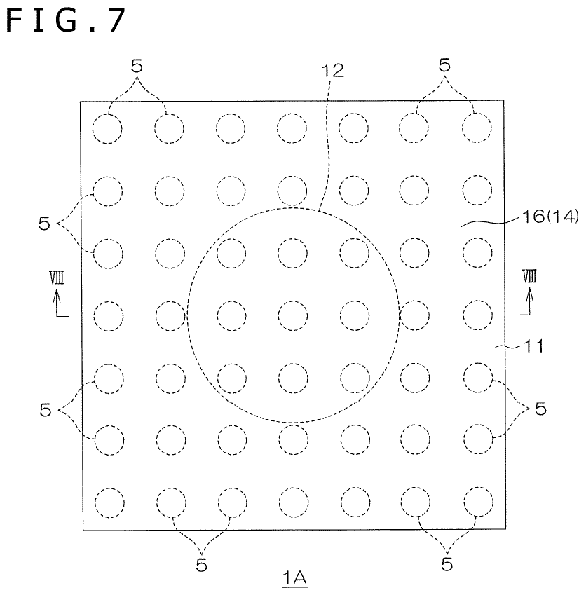

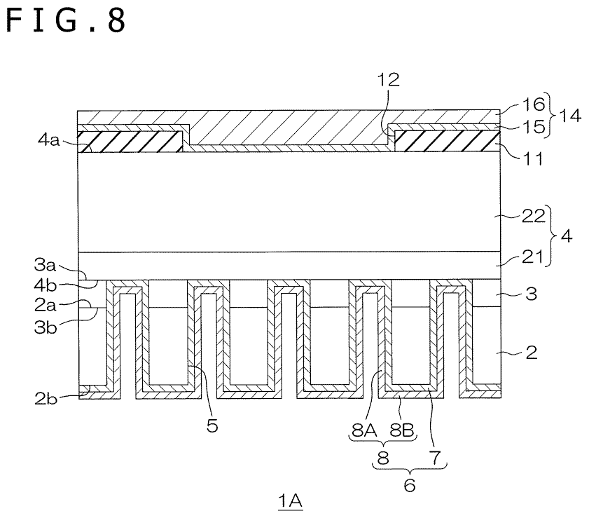

FIG. 7 is a graphic plan view for describing the configuration of a second semiconductor apparatus 1A mounted on a semiconductor package according to the present embodiment. FIG. 8 is a graphic cross-sectional view taken along line VIII-VIII in FIG. 7. In FIGS. 7 and 8, the same reference signs as in FIGS. 1 and 2 are provided to the parts corresponding to the components in FIGS. 1 and 2.

In FIG. 8, the ratio of the diameter of the trench to the width of the second semiconductor apparatus 1A is depicted larger than the actual ratio for the convenience of description. Therefore, the number of depicted trenches in FIG. 8 is smaller than it actually is.

In the second semiconductor apparatus 1A, the mode of the trench 5 is different from that in the first semiconductor apparatus 1 illustrated in FIGS. 1 and 2.

Specifically, a plurality of trenches 5 are formed. The plurality of trenches 5 are dug from the second main surface 2b of the Si substrate 2 toward the second main surface 4b of the drift layer 4 and formed on the laminated body of the Si substrate 2 and the buffer layer 3. The plurality of trenches 5 penetrate the Si substrate 2 and the buffer layer 3 and reach the second main surface 4b of the drift layer 4. In this mode, the bottom surface of each trench 5 is formed by the second main surface 4b of the drift layer 4.

The plurality of trenches 5 are arranged in a grid pattern in plan view. In this mode, the plurality of trenches 5 are arranged in a matrix pattern in plan view. The interval between two trenches 5 adjacent to each other in the row direction or the column direction is approximately 10 μm. Note that the plurality of trenches 5 may be arranged in a staggered pattern in plan view.

The shape of the cross section of the trench 5 is optional, and the shape may be an elliptical shape or a polygonal shape. The size of the cross section (area of cross section) of the trench 5 and the interval between two adjacent trenches 5 can be set as desired.

As in the first semiconductor apparatus 1 of FIGS. 1 and 2, the ohmic metal 7 that comes into ohmic contact with the second main surface 4b of the drift layer 4 is formed on the entire inner surfaces (bottom surface and side surface) of the trench 5 and the entire second main surface 2b of the Si substrate 2.

As in the first semiconductor apparatus 1 of FIGS. 1 and 2, the electrode metal 8 is formed on the surface of the ohmic metal 7 in the trench 5. The electrode metal 8 includes the first part 8A covering the surface of the ohmic metal 7 in the trench 5, and the second part 8B covering the surface of the ohmic metal 7 outside the trench 5. The second part 8B covers the entire second main surface 2b of the Si substrate 2. In this way, the cathode electrode 6 including the ohmic metal 7 and the electrode metal 8 is formed.

Note that the electrode metal 8 may be completely embedded into the trench 5. In that case, the entire back surface of the electrode metal 8 may be flat.

The region corresponding to the bottom surface of the trench 5 in the second main surface 4b of the drift layer 4 is covered by the ohmic metal 7 of the cathode electrode 6. In other words, the region corresponding to the bottom surface of the trench 5 in the second main surface 4b of the drift layer 4 is in contact with the ohmic metal 7. The other region in the second main surface 4b of the drift layer 4 (region outside the periphery of the trench 5 in plan view) is in contact with the first main surface 3a of the buffer layer 3.

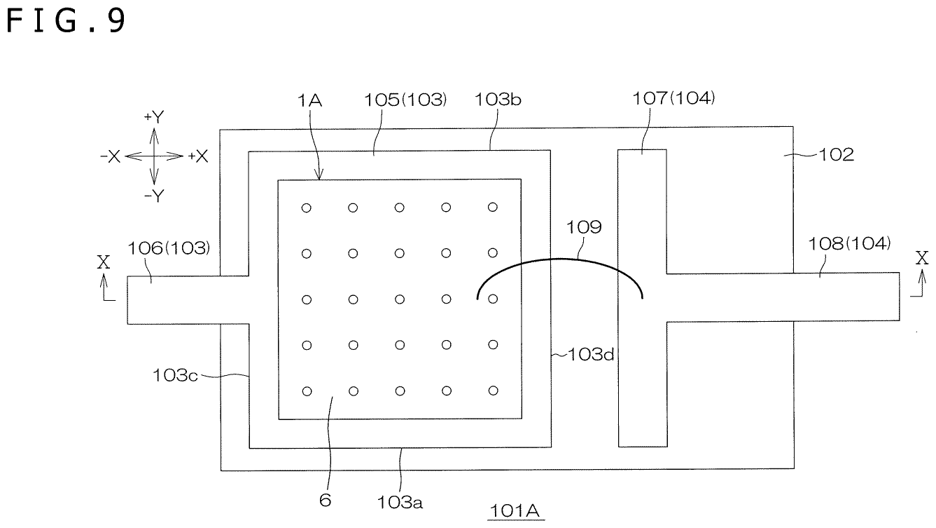

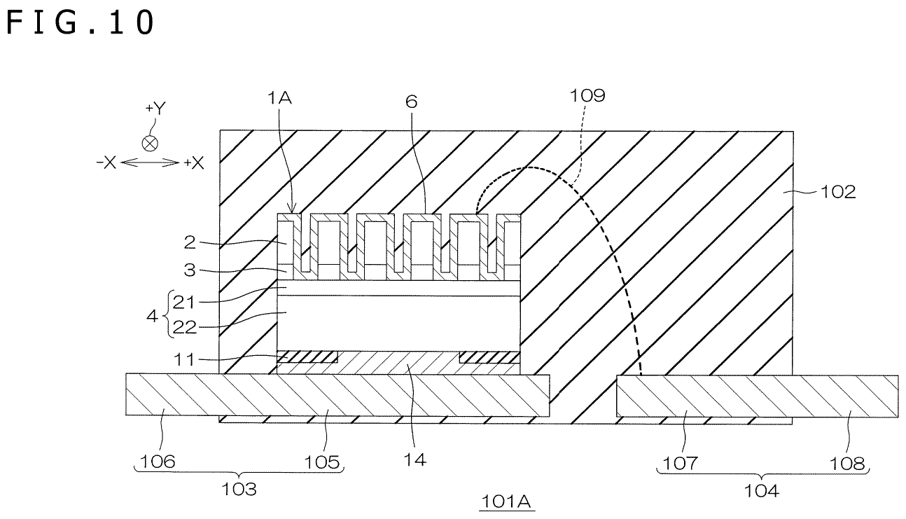

FIG. 9 is a schematic plan view of the semiconductor package provided with the second semiconductor apparatus 1A. FIG. 10 is a cross-sectional view taken along line X-X in FIG. 9. In FIGS. 9 and 10, the same reference signs as in FIGS. 3 and 4 are provided to the parts corresponding to the components in FIGS. 3 and 4.

For the convenience of description, the +X direction, the −X direction, the +Y direction, and the −Y direction illustrated in FIGS. 9 and 10 may be used below. The +X direction is a predetermined direction along the main surfaces 2a and 2b of the substrate 2. The +Y direction is a predetermined direction along the main surfaces 2a and 2b of the substrate 2 and is a direction orthogonal to the +X direction.

The −X direction is a direction opposite the +X direction. The −Y direction is a direction opposite the +Y direction. The +X direction and the −X direction may collectively and simply be referred to as the “X direction.” The +Y direction and the −Y direction may collectively and simply be referred to as the “Y direction.”

In FIGS. 9 and 10, the second semiconductor apparatus 1A illustrated in FIGS. 7 and 8 is vertically inverted and arranged.

A semiconductor package 101A includes the resin package 102 in a flat cuboid shape, and the anode terminal 103 and the cathode terminal 104 sealed in the resin package 102.

The two terminals 103 and 104 include metal plates formed in a predetermined shape. The anode terminal 103 includes the island 105 and the terminal part 106.

The island 105 has a rectangular shape including the two sides 103a and 103b parallel to each other in the X direction and the two sides 103c and 103d parallel to each other in the Y direction in plan view. The terminal part 106 extends in the −X direction from the center part of the length of the one side 103c of the island 105 and has a rectangular shape elongated in the X direction in plan view.

The cathode terminal 104 is arranged on the opposite side of the terminal part 106 with respect to the island 105. The cathode terminal 104 includes the wire connection 107 and the terminal part 108.

The wire connection 107 is arranged at an interval from the side 103d of the island 105 in the +X direction, and the wire connection 107 has a rectangular shape elongated in the Y direction in plan view. The terminal part 108 extends in the +X direction from the center part of the length of the wire connection 107 and has a rectangular shape elongated in the X direction in plan view.

The second semiconductor apparatus 1A is mounted on the center part of the island 105 of the anode terminal 103 through flip-chip bonding. Specifically, the second semiconductor apparatus 1A is vertically inverted, and the anode electrode 14 of the second semiconductor apparatus 1A is connected to the upper surface of the island 105.

The cathode electrode 6 of the second semiconductor apparatus 1A is connected to the wire connection 107 of the cathode terminal 104 through the bonding wire 109.

The second semiconductor apparatus 1A, the island 105, the base end of the terminal part 106, the wire connection 107, the base end of the terminal part 108, and the bonding wire 109 are sealed in the resin package 102. The front end of the terminal part 106 protrudes in the −X direction from the end surface of the resin package 102 on the −X side. The front end of the terminal part 108 protrudes in the +X direction from the end surface of the resin package 102 on the +X side.

In the second semiconductor apparatus 1A, heat is easily generated at the boundary of the anode electrode 14 and the first main surface 4a of the drift layer 4. In the semiconductor package 101A, the anode electrode 14 is connected to the island 105 of the anode terminal 103, and the heat generated at the boundary of the anode electrode 14 and the first main surface 4a of the drift layer 4 can be easily released.

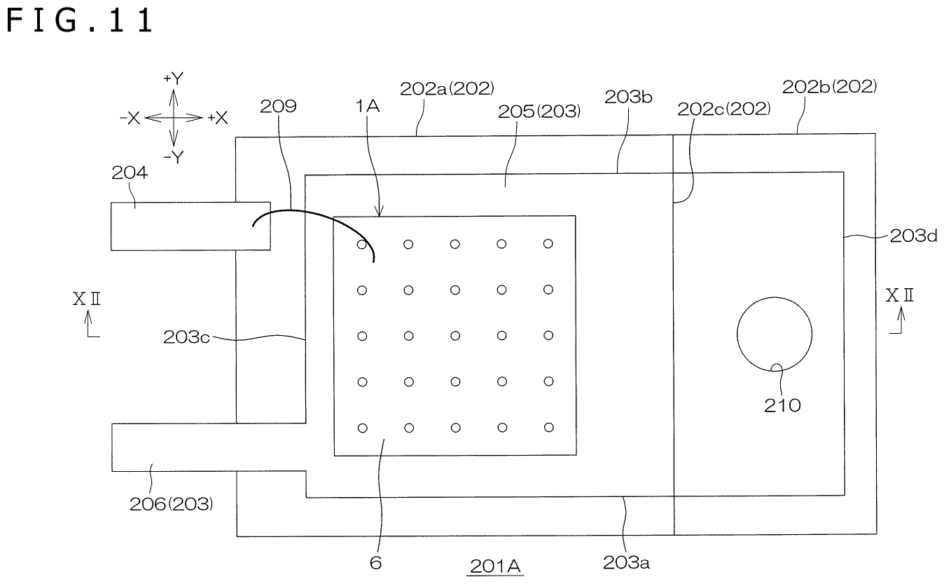

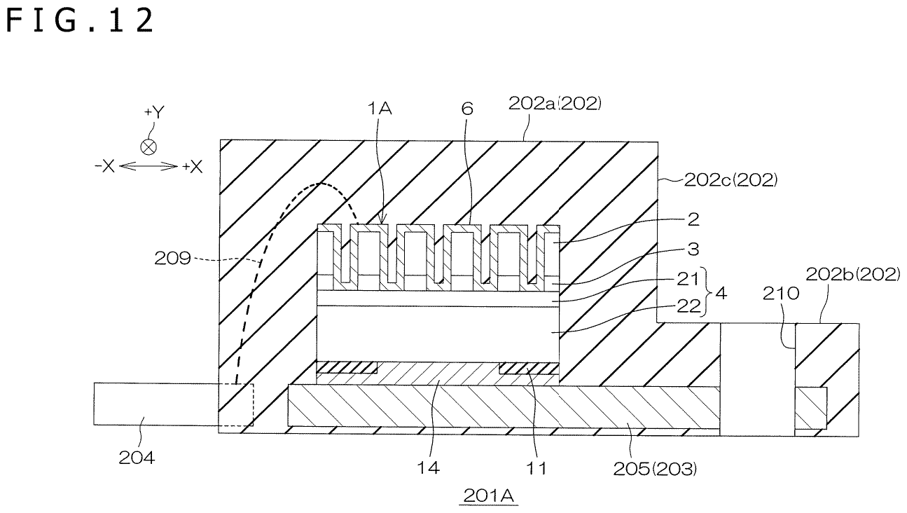

FIG. 11 is a schematic plan view illustrating another example of the semiconductor package provided with the second semiconductor apparatus 1A. FIG. 12 is a cross-sectional view taken along line XII-XII in FIG. 11. In FIGS. 11 and 12, the same reference signs as in FIGS. 5 and 6 are provided to the parts corresponding to the components in FIGS. 5 and 6.

For the convenience of description, the +X direction, the −X direction, the +Y direction, and the −Y direction illustrated in FIGS. 11 and 12 may be used below. The +X direction is a predetermined direction along the main surfaces 2a and 2b of the substrate 2. The +Y direction is a predetermined direction along the main surfaces 2a and 2b of the substrate 2 and is a direction orthogonal to the +X direction.

The −X direction is a direction opposite the +X direction. The −Y direction is a direction opposite the +Y direction. The +X direction and the −X direction may collectively and simply be referred to as the “X direction.” The +Y direction and the −Y direction may collectively and simply be referred to as the “Y direction.”

In FIGS. 11 and 12, the second semiconductor apparatus 1A illustrated in FIGS. 7 and 8 is vertically inverted and arranged.

A semiconductor package 201A includes the resin package 202 in a rectangular shape in plan view, and the anode terminal 203 and the cathode terminal 204 sealed in the resin package 202.

The two terminals 203 and 204 include metal plates formed in a predetermined shape. The anode terminal 203 includes the island 205 and the terminal part 206. The island 205 has a rectangular shape including the two sides 203a and 203b parallel to each other in the X direction and the two sides 203c and 203d parallel to each other in the Y direction in plan view. The terminal part 206 linearly extends in the −X direction from the position closer to the −Y side end of the one side 203c of the island 205 and has a rectangular shape elongated in the X direction in plan view.

The cathode terminal 204 has a shape similar to the terminal part 206 of the anode terminal 203 in plan view, and the cathode terminal 204 is arranged at an interval from the terminal part 206 of the anode terminal 203 in the +Y direction. The +X side end of the cathode terminal 204 is arranged at an interval from the side 203c of the island 205 in the −X direction.

The second semiconductor apparatus 1A is mounted on the center part of the island 205 of the anode terminal 203 through flip-chip bonding. Specifically, the second semiconductor apparatus 1A is vertically inverted, and the anode electrode 14 of the second semiconductor apparatus 1A is connected to the upper surface of the island 205.

The cathode electrode 6 of the second semiconductor apparatus 1A is connected to the +X side part of the cathode terminal 204 in the length direction through the bonding wire 209.

The resin package 202 includes the main portion 202a in a cuboid shape, and the thin portion 202b arranged on the +X side of the main portion 202a and thinner than the main portion 202a. The bottom surface of the main portion 202a and the bottom surface of the thin portion 202b are flush with each other. The step portion 202c is formed between the upper surface of the thin portion 202b and the upper surface of the main portion 202a.

The main portion 202a seals the second semiconductor apparatus 1A, the part of the island 205 excluding the +X direction end, the base end of the terminal part 206, the +X side part of the cathode terminal 204 in the length direction, and the bonding wire 209. The thin portion 202b seals the +X direction end of the island 205.

The front end of the terminal part 206 protrudes in the −X direction from the end surface of the main portion 202a on the −X side. The −X side part of the cathode terminal 204 in the length direction protrudes in the −X direction from the end surface of the main portion 202a on the −X side.

The through hole 210 penetrating the thin portion 202b and the +X side end of the island 205 in the vertical direction is formed near the center of the thin portion 202b in plan view.

In the second semiconductor apparatus 1A, heat is easily generated at the boundary of the anode electrode 14 and the first main surface 4a of the drift layer 4. In the semiconductor package 201A, the anode electrode 14 is connected to the island 205 of the anode terminal 203, and the heat generated at the boundary of the anode electrode 14 and the first main surface 4a of the drift layer 4 can be easily released.

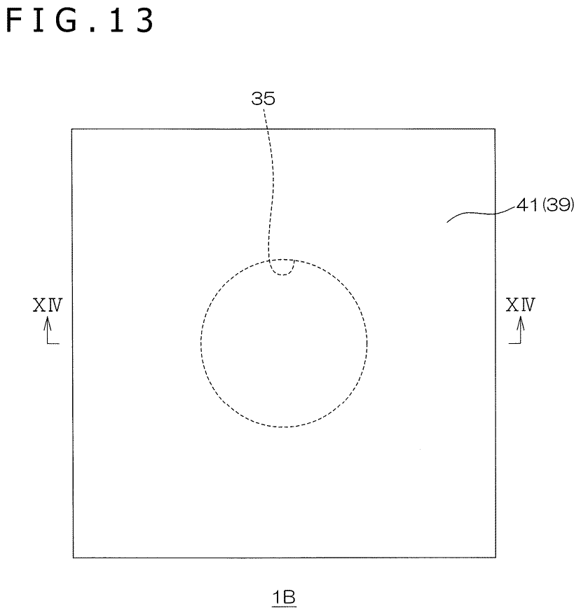

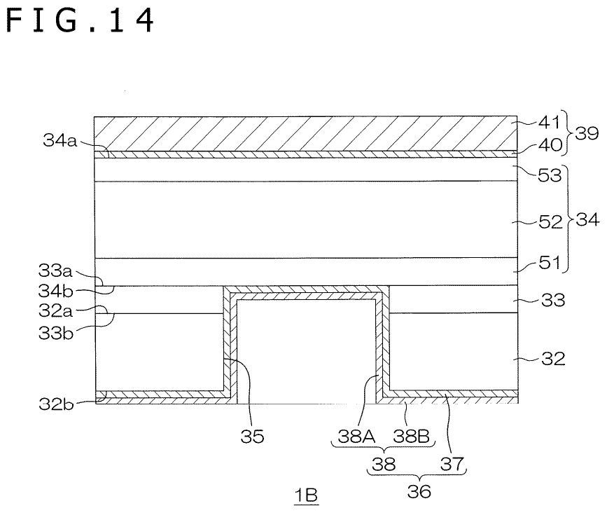

FIG. 13 is a graphic plan view for describing the configuration of a third semiconductor apparatus mounted on a semiconductor package according to the present embodiment. FIG. 14 is a graphic cross-sectional view taken along line XIV-XIV in FIG. 13.

A third semiconductor apparatus 1B is a positive intrinsic negative (PIN) diode. The third semiconductor apparatus 1B is formed in, for example, a rectangular chip shape in plan view as illustrated in FIG. 13. The length of each of four sides of the third semiconductor apparatus 1B in plan view is, for example, approximately several mm. In the embodiment, the length of each of the four sides of the third semiconductor apparatus 1B in plan view is approximately 1 mm (1000 μm).

The third semiconductor apparatus 1B includes a Si (silicon) substrate 32 including a first main surface (front surface) 32a and a second main surface (back surface) 32b. The Si substrate 32 is rectangular in plan view. The third semiconductor apparatus 1B also includes a buffer layer 33 formed on the first main surface 32a of the Si substrate 32. The buffer layer 33 includes a first main surface (front surface) 33a and a second main surface (back surface) 33b. The buffer layer 33 has a rectangular shape in line with the Si substrate 32.

The third semiconductor apparatus 1B further includes a drift layer 34 including a gallium semiconductor layer and formed on the first main surface 33a of the buffer layer 33. The drift layer 34 includes a first main surface (front surface) 34a and a second main surface (back surface) 34b. The drift layer 34 has a rectangular shape in line with the buffer layer 33 in plan view. The first main surface 34a of the drift layer 34 is an example of the “first surface of drift layer” in the present disclosure, and the second main surface 34b of the drift layer 34 is an example of the “second surface of drift layer” in the present disclosure.

The Si substrate 32 is doped with n-type impurities. Phosphorus (P), for example, is used as the n-type impurities. The n-type impurity concentration in the Si substrate 32 may be, for example, approximately 1×10¹⁶ cm⁻³ to 1×10²⁰ cm⁻³. The first main surface 32a and the second main surface 32b of the Si substrate 32 are (111) planes. The thickness of the Si substrate 32 is, for example, approximately 50 to 1000 μm. In the embodiment, the thickness of the Si substrate 32 is approximately 100 μm.

The buffer layer 33 in the embodiment contains aluminum nitride (AlN) having a crystal structure with in-plane six-fold symmetry. The first main surface 33a and the second main surface 33b of the buffer layer 33 containing aluminum nitride are (0001) planes. That is, a hexagonal material including (0001) planes as main surfaces is used as the buffer layer 33 in the embodiment. The thickness of the buffer layer 33 is, for example, approximately 100 to 200 nm. In the embodiment, the thickness of the buffer layer 33 is approximately 160 nm.

The reason that the buffer layer 33 is provided is as follows. If the drift layer 34 including the gallium semiconductor layer is directly formed on the Si substrate 32, a high-quality drift layer 34 cannot be obtained due to the eutectic reaction of the silicon of the Si substrate 32 and the gallium of the drift layer 34. Therefore, the buffer layer 33 is provided between the Si substrate 32 and the drift layer 34 to suppress the reaction (mixed crystal) of the silicon of the Si substrate 32 and the gallium oxide of the drift layer 34.

The drift layer 34 includes a gallium semiconductor layer. The gallium semiconductor layer includes a Ga₂O₃ semiconductor layer and a GaN semiconductor layer. The Ga₂O₃ semiconductor layer includes an (Inₓ₁Ga₍₁₋ₓ₁₎)₂O₃ layer, an (Alₓ₂Ga₍₁₋ₓ₂₎)₂O₃ layer, for example. The GaN semiconductor layer includes a Scₓ₃Ga₍₁₋ₓ₃₎N layer, a Tlₓ₄Ga_{(1_x4)}N layer, an Alₓ₅Ga₍₁₋ₓ₅₎N layer, for example.

In the embodiment, the drift layer 34 includes a first drift layer 51 as a lower layer formed on the first main surface 33a of the buffer layer 33, a second drift layer 52 as a middle layer laminated on the first drift layer 51, and a third drift layer 53 as an upper layer laminated on the second drift layer 52.

In the embodiment, the first drift layer 51 includes a GaN semiconductor layer doped with n-type impurities. Examples of the GaN semiconductor layer include a Scₓ₃Ga₍₁₋ₓ₃₎N (0 ≤x3<1) layer, a Tlₓ₄Ga₍₁₋ₓ₄₎N (0≤x4<1) layer, and an Alₓ₅Ga₍₁₋ₓ₅₎N (0≤x5<1) layer.

In the embodiment, the first drift layer 51 includes a GaN layer doped with n-type impurities. The first drift layer 51 may be an AlGaN layer doped with n-type impurities. In the embodiment, the n-type impurities contain silicon (Si). The concentration of the n-type impurities is approximately 1×10¹⁷ cm⁻³ to 1×10²⁰ cm⁻³. The film thickness of the first drift layer 51 is approximately 200 nm. Note that the n-type impurities may contain tin (Sn).

The second drift layer 52 includes an undoped GaN semiconductor layer. In the specification, the undoped GaN semiconductor layer denotes a GaN semiconductor layer with the impurity concentration of smaller than 1×10¹⁶/cm³. Examples of the GaN semiconductor layer include a Scₓ₃Ga₍₁₋ₓ₃₎N (0≤x3<1) layer, Tlₓ₄Ga₍₁₋ₓ₄₎N (0≤x4<1) layer, and Alₓ₅Ga₍₁₋ₓ₅₎N (0≤x5<1) layer. In the embodiment, the second drift layer 52 includes an undoped GaN layer. The second drift layer 52 may be an undoped AlGaN layer. The film thickness of the second drift layer 52 is approximately 6 μm.

In the embodiment, the third drift layer 53 includes a GaN semiconductor layer doped with p-type impurities. Examples of the GaN semiconductor layer include a Scₓ₃Ga₍₁₋ₓ₃₎N (0≤x3<1) layer, Tlₓ₄Ga₍₁₋ₓ₄₎N (0≤x4<1) layer, and Alₓ₅Ga₍₁₋ₓ₅₎N (0≤x5<1) layer.

In the embodiment, the third drift layer 53 includes a GaN layer doped with p-type impurities. The third drift layer 53 may be an AlGaN layer doped with p-type impurities. In the embodiment, the p-type impurities contain manganese (Mg). The concentration of the p-type impurities is approximately 1×10¹⁷ cm⁻³ to 1×10²⁰ cm⁻³. The film thickness of the third drift layer 53 is approximately 200 nm.

A laminated body of the Si substrate 32 and the buffer layer 33 is provided with one trench 35 formed by digging the laminated body from the center part of the second main surface 32b of the Si substrate 32 toward the second main surface 34b of the drift layer 34. The trench 35 penetrates the Si substrate 32 and the buffer layer 33 and reaches the second main surface 34b of the drift layer 34. The trench 35 is formed to reduce the resistivity from the first main surface 32a of the Si substrate 32 to the second main surface 32b of the Si substrate 32.

In the embodiment, the bottom surface of the trench 35 is formed by the second main surface 34b of the drift layer 34. In the embodiment, the shape of the cross section of the trench 35 is a circular shape. In the embodiment, the diameter of the trench 35 is approximately 380 μm.

An inside metal 37 that comes into contact with the second main surface 34b of the drift layer 34 is formed on the entire inner surfaces (bottom surface and side surface) of the trench 35 and the entire second main surface 32b of the Si substrate 32. In the embodiment, the inside metal 37 contains nickel (Ni). The thickness of the inside metal 37 is, for example, approximately 0.3 to 300 nm.

An outside metal 38 is formed on the surface of the inside metal 37. The outside metal 38 contains copper (Cu), gold (Au), for example. In the embodiment, the outside metal 38 contains copper (Cu). The outside metal 38 includes a first part 38A covering the surface of the inside metal 37 in the trench 35, and a second part 38B covering the surface of the inside metal 37 outside the trench 35. The second part 38B covers the entire second main surface 32b of the Si substrate 32.

Note that the outside metal 38 may be completely embedded into the trench 35. In that case, the entire back surface (lower surface) of the outside metal 38 may be flat.

The inside metal 37 and the outside metal 38 form a cathode electrode 36. That is, the cathode electrode 36 in the embodiment has a multi-layer structure (two-layer structure in the embodiment) including the inside metal 37 connected to the Si substrate 32 and the outside metal 38 laminated on the inside metal 37. In the embodiment, the outside metal 38 is a part of the cathode electrode 36 exposed to the outermost surface of the third semiconductor apparatus 1B and connected to a bonding wire, for example.

The region corresponding to the bottom surface of the trench 35 in the second main surface 34b of the drift layer 34 is covered by the inside metal 37 of the cathode electrode 36. In other words, the region corresponding to the bottom surface of the trench 35 in the second main surface 34b of the drift layer 34 is in contact with the inside metal 37 (cathode electrode 36). The other region in the second main surface 34b of the drift layer 34 (region not provided with the trench 35 in plan view) is in contact with the first main surface 33a of the buffer layer 33.

An anode electrode 39 is formed on the first main surface 34a of the drift layer 34.

In the embodiment, the anode electrode 39 has a rectangular shape in line with the drift layer 34 in plan view. In the embodiment, the anode electrode 39 functions as a terminal for flip-chip bonding of the third semiconductor apparatus 1B, and the anode electrode 39 may be referred to as an external terminal.

The anode electrode 39 in the embodiment has a multi-layer structure (two-layer structure in the embodiment) including an inside metal 40 connected to the drift layer 34 and an outside metal 41 laminated on the inside metal 40.

In the embodiment, the inside metal 40 contains titanium (Ti). The thickness of the inside metal 40 is, for example, approximately 0.02 to 0.20 μm in the embodiment.

The outside metal 41 contains copper (Cu), gold (Au), for example. In the embodiment, the outside metal 41 contains copper (Cu). The thickness of the outside metal 41 is larger than the thickness of the inside metal 40 and is, for example, approximately 0.5 to 5.0 μm in the embodiment.

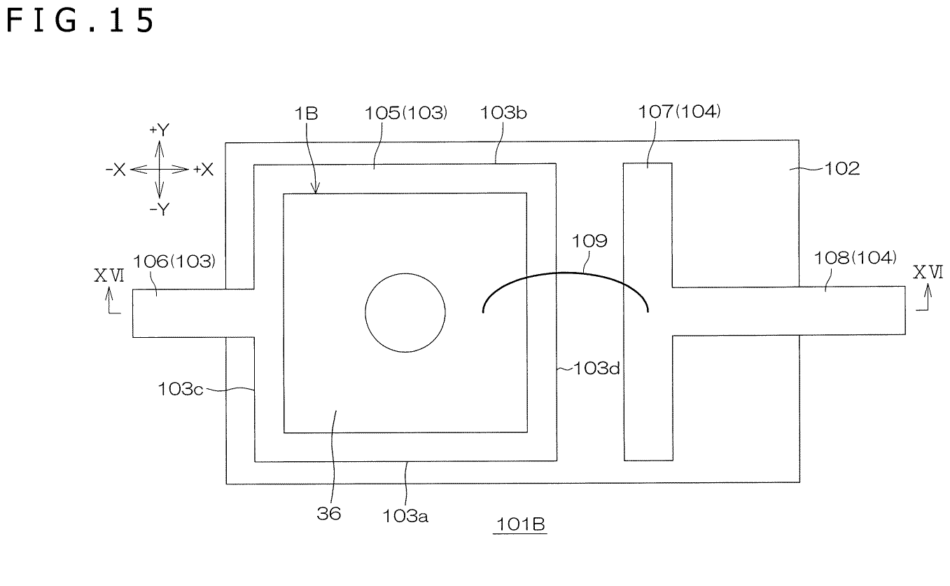

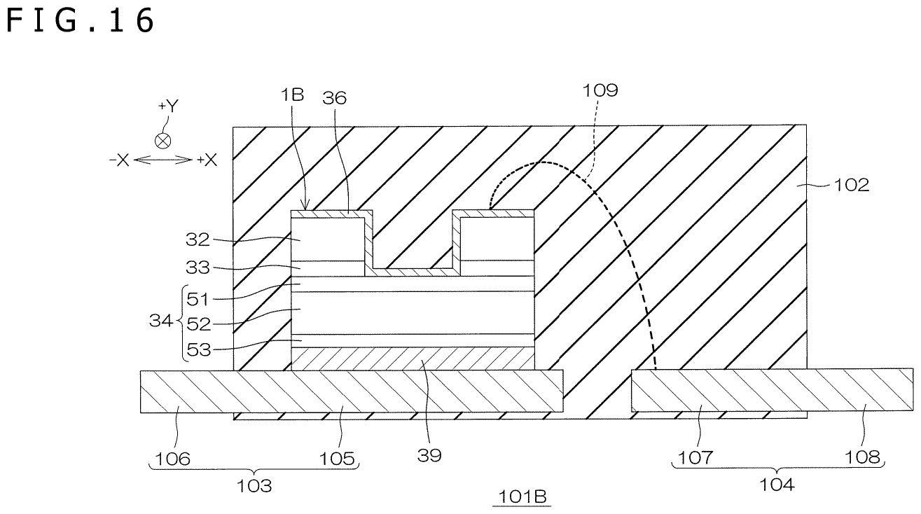

FIG. 15 is a schematic plan view of the semiconductor package provided with the third semiconductor apparatus 1B. FIG. 16 is a cross-sectional view taken along line XVI-XVI in FIG. 15. In FIGS. 15 and 16, the same reference signs as in FIGS. 3 and 4 are provided to the parts corresponding to the components in FIGS. 3 and 4.

For the convenience of description, the +X direction, the −X direction, the +Y direction, and the −Y direction illustrated in FIGS. 15 and 16 may be used below. The +X direction is a predetermined direction along the main surfaces 32a and 32b of the Si substrate 32. The +Y direction is a predetermined direction along the main surfaces 32a and 32b of the Si substrate 32 and is a direction orthogonal to the +X direction.

The −X direction is a direction opposite the +X direction. The −Y direction is a direction opposite the +Y direction. The +X direction and the −X direction may collectively and simply be referred to as the “X direction.” The +Y direction and the −Y direction may collectively and simply be referred to as the “Y direction.”

In FIGS. 15 and 16, the third semiconductor apparatus 1B illustrated in FIGS. 13 and 14 is vertically inverted and arranged.

A semiconductor package 101B includes the resin package 102 in a cuboid shape, and the anode terminal 103 and the cathode terminal 104 sealed in the resin package 102.

The two terminals 103 and 104 include metal plates formed in a predetermined shape. The anode terminal 103 includes the island 105 and the terminal part 106.

The island 105 has a rectangular shape including the two sides 103a and 103b parallel to each other in the X direction and the two sides 103c and 103d parallel to each other in the Y direction in plan view. The terminal part 106 extends in the −X direction from the center part of the length of the one side 103c of the island 105 and has a rectangular shape elongated in the X direction in plan view.

The cathode terminal 104 is arranged on the opposite side of the terminal part 106 with respect to the island 105. The cathode terminal 104 includes the wire connection 107 and the terminal part 108.

The wire connection 107 is arranged at an interval from the side 103d of the island 105 in the +X direction, and the wire connection 107 has a rectangular shape elongated in the Y direction in plan view. The terminal part 108 extends in the +X direction from the center part of the length of the wire connection 107 and has a rectangular shape elongated in the X direction in plan view.

The third semiconductor apparatus 1B is mounted on the center part of the island 105 of the anode terminal 103 through flip-chip bonding. Specifically, the third semiconductor apparatus 1B is vertically inverted, and the anode electrode 39 of the third semiconductor apparatus 1B is connected to the upper surface of the island 105.

The cathode electrode 36 of the third semiconductor apparatus 1B is connected to the wire connection 107 of the cathode terminal 104 through the bonding wire 109.

The third semiconductor apparatus 1B, the island 105, the base end of the terminal part 106, the wire connection 107, the base end of the terminal part 108, and the bonding wire 109 are sealed in the resin package 102. The front end of the terminal part 106 protrudes in the −X direction from the end surface of the resin package 102 on the −X side. The front end of the terminal part 108 protrudes in the +X direction from the end surface of the resin package 102 on the +X side.

In the third semiconductor apparatus 1B, heat is easily generated at the boundary of the anode electrode 39 and the first main surface 34a of the drift layer 34. In the semiconductor package 101B, the anode electrode 39 is connected to the island 105 of the anode terminal 103, and the heat generated at the boundary of the anode electrode 39 and the first main surface 34a of the drift layer 34 can be easily released.

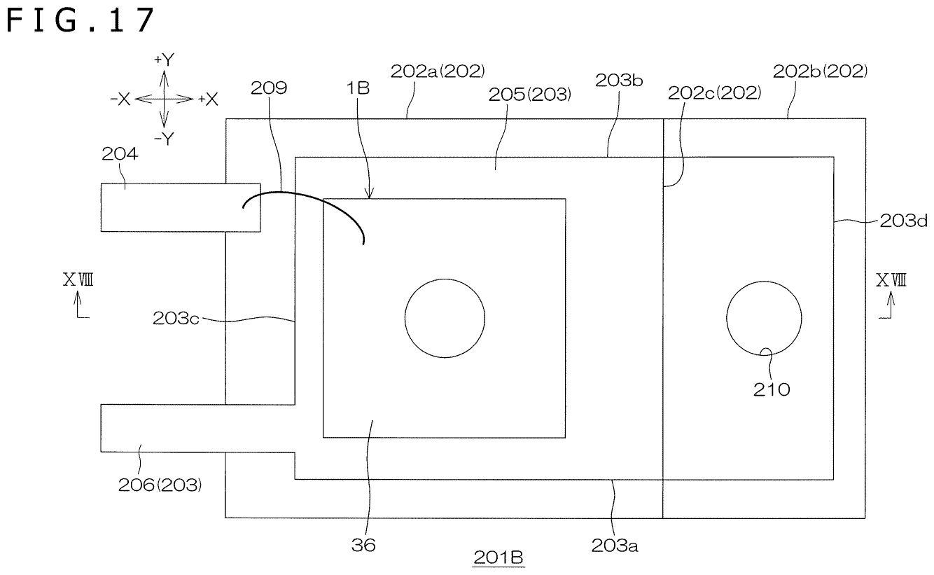

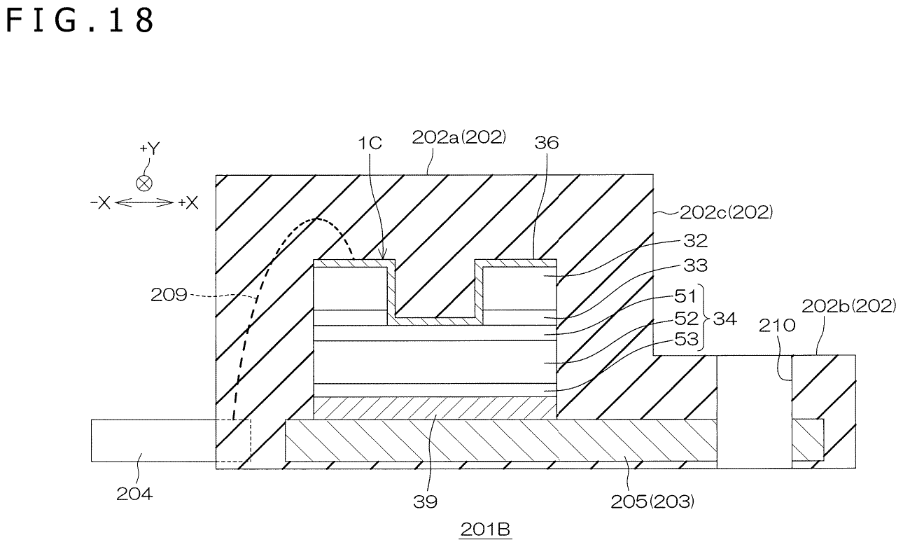

FIG. 17 is a schematic plan view illustrating another example of another semiconductor package provided with the third semiconductor apparatus 1B. FIG. 18 is a cross-sectional view taken along line XVIII-XVIII in FIG. 17. In FIGS. 17 and 18, the same reference signs as in FIGS. 5 and 6 are provided to the parts corresponding to the components in FIGS. 5 and 6.

For the convenience of description, the +X direction, the −X direction, the +Y direction, and the −Y direction illustrated in FIGS. 17 and 18 may be used below. The +X direction is a predetermined direction along the main surfaces 32a and 32b of the substrate 32. The +Y direction is a predetermined direction along the main surfaces 32a and 32b of the substrate 32 and is a direction orthogonal to the +X direction.

The −X direction is a direction opposite the +X direction. The −Y direction is a direction opposite the +Y direction. The +X direction and the −X direction may collectively and simply be referred to as the “X direction.” The +Y direction and the −Y direction may collectively and simply be referred to as the “Y direction.”

In FIGS. 17 and 18, the third semiconductor apparatus 1B illustrated in FIGS. 13 and 14 is vertically inverted and arranged.

A semiconductor package 201B includes the resin package 202 in a rectangular shape in plan view, and the anode terminal 203 and the cathode terminal 204 sealed in the resin package 202.

The two terminals 203 and 204 include metal plates formed in a predetermined shape. The anode terminal 203 includes the island 205 and the terminal part 206. The island 205 has a rectangular shape including the two sides 203a and 203b parallel to each other in the X direction and the two sides 203c and 203d parallel to each other in the Y direction in plan view. The terminal part 206 linearly extends in the −X direction from the position closer to the −Y side end of the one side 203c of the island 205 and has a rectangular shape elongated in the X direction in plan view.

The cathode terminal 204 has a shape similar to the terminal part 206 of the anode terminal 203 in plan view, and the cathode terminal 204 is arranged at an interval from the terminal part 206 of the anode terminal 203 in the +Y direction. The +X side end of the cathode terminal 204 is arranged at an interval from the side 203c of the island 205 in the −X direction.

The third semiconductor apparatus 1B is mounted on the center part of the island 205 of the anode terminal 203 through flip-chip bonding. Specifically, the third semiconductor apparatus 1B is vertically inverted, and the anode electrode 39 of the third semiconductor apparatus 1B is connected to the upper surface of the island 205.

The cathode electrode 36 of the third semiconductor apparatus 1B is connected to the +X side part of the cathode terminal 204 in the length direction through the bonding wire 209.

The resin package 202 includes the main portion 202a in a cuboid shape, and the thin portion 202b arranged on the +X side of the main portion 202a and thinner than the main portion 202a. The bottom surface of the main portion 202a and the bottom surface of the thin portion 202b are flush with each other. The step portion 202c is formed between the upper surface of the thin portion 202b and the upper surface of the main portion 202a.

The main portion 202a seals the third semiconductor apparatus 1B, the part of the island 205 excluding the +X direction end, the base end of the terminal part 206, the +X side part of the cathode terminal 204 in the length direction, and the bonding wire 209. The thin portion 202b seals the +X direction end of the island 205.

The front end of the terminal part 206 protrudes in the −X direction from the end surface of the main portion 202a on the −X side. The −X side part of the cathode terminal 204 in the length direction protrudes in the −X direction from the end surface of the main portion 202a on the −X side.

The through hole 210 penetrating the thin portion 202b and the +X side end of the island 205 in the vertical direction is formed near the center of the thin portion 202b in plan view.

In the third semiconductor apparatus 1B, heat is easily generated at the boundary of the anode electrode 39 and the first main surface 34a of the drift layer 34. In the semiconductor package 201B, the anode electrode 39 is connected to the island 205 of the anode terminal 203, and the heat generated at the boundary of the anode electrode 39 and the first main surface 34a of the drift layer 34 can be easily released.

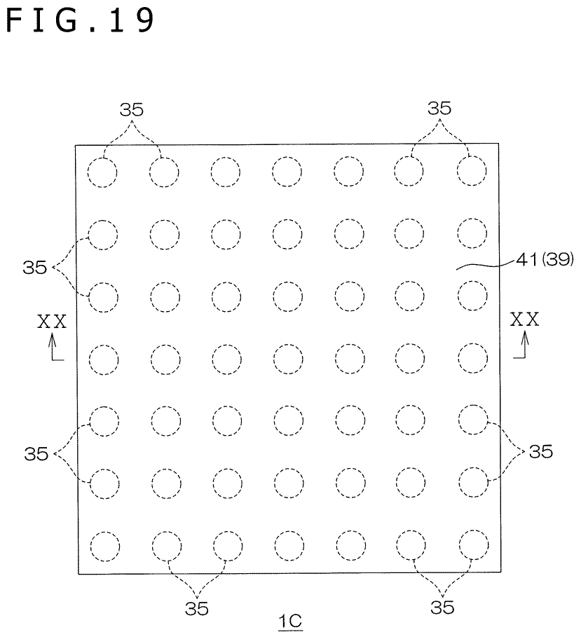

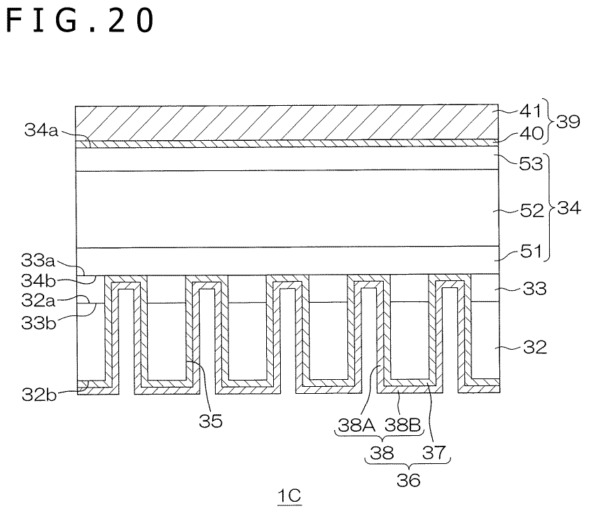

FIG. 19 is a graphic plan view for describing the configuration of a fourth semiconductor apparatus mounted on a semiconductor package according to the present embodiment. FIG. 20 is a graphic cross-sectional view taken along line XX-XX in FIG. 19. In FIGS. 19 and 20, the same reference signs as in FIGS. 13 and 14 are provided to the parts corresponding to the components in FIGS. 13 and 14.

In FIG. 20, the ratio of the diameter of the trench to the width of a fourth semiconductor apparatus 1C is depicted larger than the actual ratio for the convenience of description. Therefore, the number of depicted trenches in FIG. 20 is smaller than it actually is.

In the fourth semiconductor apparatus 1C, the mode of the trench 35 is different from the third semiconductor apparatus 1B illustrated in FIGS. 13 and 14.

Specifically, a plurality of trenches 35 are formed. The plurality of trenches 35 are dug from the second main surface 32b of the Si substrate 32 toward the second main surface 34b of the drift layer 34 and formed on the laminated body of the Si substrate 32 and the buffer layer 33. The plurality of trenches 35 penetrate the Si substrate 32 and the buffer layer 33 and reach the second main surface 34b of the drift layer 34. In this modification, the bottom surface of each trench 35 is formed by the second main surface 34b of the drift layer 34.

The plurality of trenches 35 are arranged in a grid pattern in plan view. In this modification, the plurality of trenches 35 are arranged in a matrix pattern in plan view. The interval between two trenches 35 adjacent to each other in the row direction or the column direction is approximately 10 μm. Note that the plurality of trenches 35 may be arranged in a staggered pattern in plan view.

The shape of the cross section of the trench 35 is optional, and the shape may be an elliptical shape or a polygonal shape. The size of the cross section (area of cross section) of the trench 35 and the interval between two adjacent trenches 35 can be set as desired.

As in the third semiconductor apparatus 1B of FIGS. 13 and 14, the inside metal 37 that comes into contact with the second main surface 34b of the drift layer 34 is formed on the entire inner surfaces (bottom surface and side surface) of the trench 35 and the entire second main surface 32b of the Si substrate 32.

As in the third semiconductor apparatus 1B of FIGS. 13 and 14, the outside metal 38 is formed on the surface of the inside metal 37 in the trench 35. The outside metal 38 includes the first part 38A covering the surface of the inside metal 37 in the trench 35, and the second part 38B covering the surface of the inside metal 37 outside the trench 35. The second part 38B covers the entire second main surface 32b of the Si substrate 32. In this way, the cathode electrode 36 including the inside metal 37 and the outside metal 38 is formed.

Note that the outside metal 38 may be completely embedded into the trench 35. In that case, the entire back surface of the outside metal 38 may be flat.

The region corresponding to the bottom surface of the trench 35 in the second main surface 34b of the drift layer 34 is covered by the inside metal 37 of the cathode electrode 36. In other words, the region corresponding to the bottom surface of the trench 35 in the second main surface 34b of the drift layer 34 is in contact with the inside metal 37. The other region in the second main surface 34b of the drift layer 34 (region outside the periphery of the trench 35 in plan view) is in contact with the first main surface 33a of the buffer layer 33.

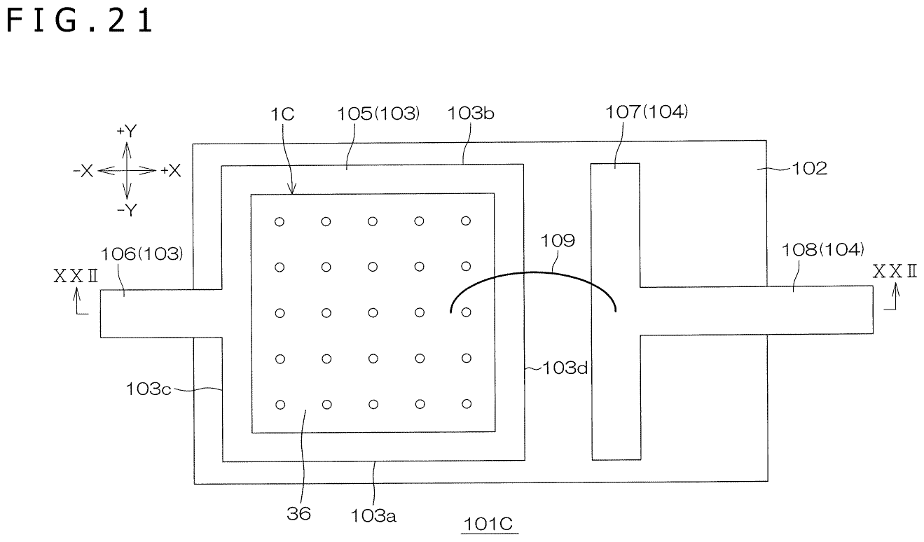

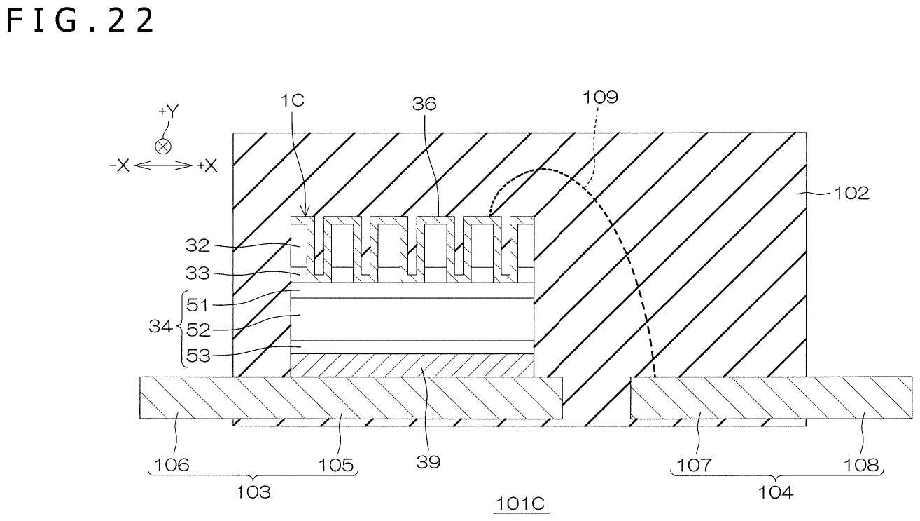

FIG. 21 is a schematic plan view of the semiconductor package provided with the fourth semiconductor apparatus 1C. FIG. 22 is a cross-sectional view taken along line XXII-XXII in FIG. 21. In FIGS. 21 and 22, the same reference signs as in FIGS. 3 and 4 are provided to the parts corresponding to the components in FIGS. 3 and 4.

For the convenience of description, the +X direction, the −X direction, the +Y direction, and the −Y direction illustrated in FIGS. 21 and 22 may be used below. The +X direction is a predetermined direction along the main surfaces 32a and 32b of the substrate 32. The +Y direction is a predetermined direction along the main surfaces 32a and 32b of the substrate 32 and is a direction orthogonal to the +X direction.

The −X direction is a direction opposite the +X direction. The −Y direction is a direction opposite the +Y direction. The +X direction and the −X direction may collectively and simply be referred to as the “X direction.” The +Y direction and the −Y direction may collectively and simply be referred to as the “Y direction.”

In FIGS. 21 and 22, the fourth semiconductor apparatus 1C illustrated in FIGS. 19 and 20 is vertically inverted and arranged.

A semiconductor package 101C includes the resin package 102 in a flat cuboid shape, and the anode terminal 103 and the cathode terminal 104 sealed in the resin package 102.

The two terminals 103 and 104 include metal plates formed in a predetermined shape. The anode terminal 103 includes the island 105 and the terminal part 106.

The island 105 has a rectangular shape including the two sides 103a and 103b parallel to each other in the X direction and the two sides 103c and 103d parallel to each other in the Y direction in plan view. The terminal part 106 extends in the −X direction from the center part of the length of the one side 103c of the island 105 and has a rectangular shape elongated in the X direction in plan view.

The cathode terminal 104 is arranged on the opposite side of the terminal part 106 with respect to the island 105. The cathode terminal 104 includes the wire connection 107 and the terminal part 108.

The wire connection 107 is arranged at an interval from the side 103d of the island 105 in the +X direction, and the wire connection 107 has a rectangular shape elongated in the Y direction in plan view. The terminal part 108 extends in the +X direction from the center part of the length of the wire connection 107 and has a rectangular shape elongated in the X direction in plan view.

The fourth semiconductor apparatus 1C is mounted on the center part of the island 105 of the anode terminal 103 through flip-chip bonding. Specifically, the fourth semiconductor apparatus 1C is vertically inverted, and the anode electrode 39 of the fourth semiconductor apparatus 1C is connected to the upper surface of the island 105.

The cathode electrode 36 of the fourth semiconductor apparatus 1C is connected to the wire connection 107 of the cathode terminal 104 through the bonding wire 109.

The fourth semiconductor apparatus 1C, the island 105, the base end of the terminal part 106, the wire connection 107, the base end of the terminal part 108, and the bonding wire 109 are sealed in the resin package 102. The front end of the terminal part 106 protrudes in the −X direction from the end surface of the resin package 102 on the −X side. The front end of the terminal part 108 protrudes in the +X direction from the end surface of the resin package 102 on the +X side.

In the fourth semiconductor apparatus 1C, heat is easily generated at the boundary of the anode electrode 39 and the first main surface 34a of the drift layer 34. In the semiconductor package 101C, the anode electrode 39 is connected to the island 105 of the anode terminal 103, and the heat generated at the boundary of the anode electrode 39 and the first main surface 34a of the drift layer 34 can be easily released.

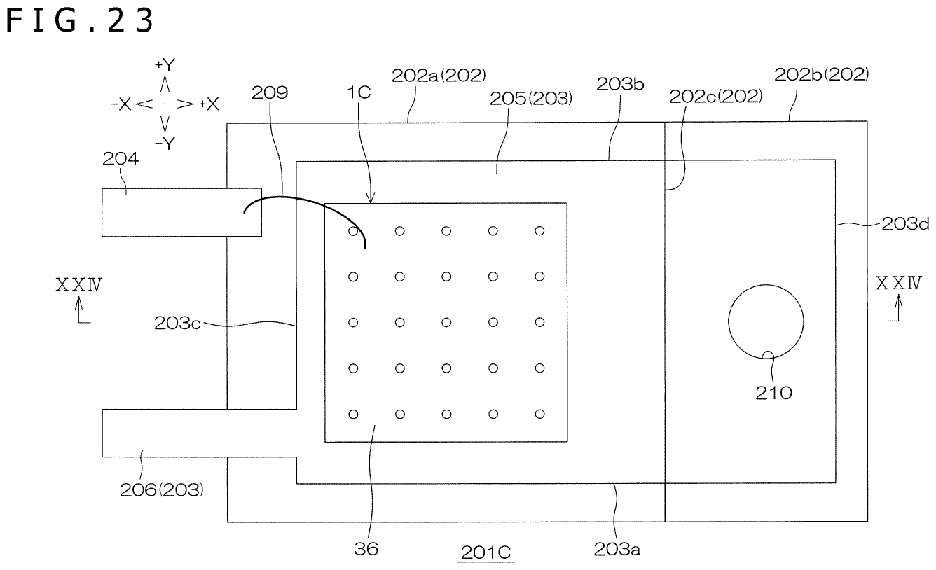

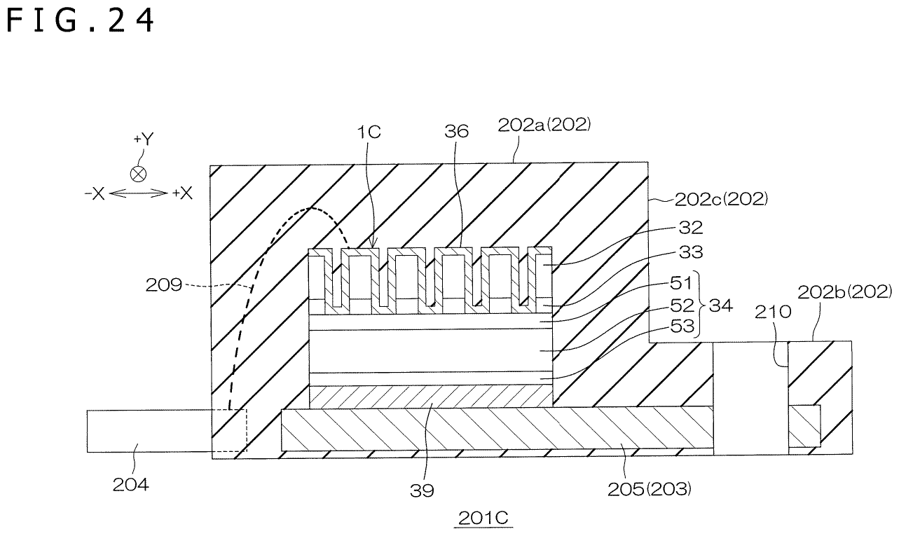

FIG. 23 is a schematic plan view illustrating another example of the semiconductor package provided with the fourth semiconductor apparatus 1C. FIG. 24 is a cross-sectional view taken along line XXIV-XXIV in FIG. 23. In FIGS. 23 and 24, the same reference signs as in FIGS. 5 and 6 are provided to the parts corresponding to the components in FIGS. 5 and 6.

For the convenience of description, the +X direction, the −X direction, the +Y direction, and the −Y direction illustrated in FIGS. 23 and 24 may be used below. The +X direction is a predetermined direction along the main surfaces 32a and 32b of the substrate 32. The +Y direction is a predetermined direction along the main surfaces 32a and 32b of the substrate 32 and is a direction orthogonal to the +X direction.

The −X direction is a direction opposite the +X direction. The −Y direction is a direction opposite the +Y direction. The +X direction and the −X direction may collectively and simply be referred to as the “X direction.” The +Y direction and the −Y direction may collectively and simply be referred to as the “Y direction.”

In FIGS. 23 and 24, the fourth semiconductor apparatus 1C illustrated in FIGS. 19 and 20 is vertically inverted and arranged.

A semiconductor package 201C includes the resin package 202 in a rectangular shape in plan view, and the anode terminal 203 and the cathode terminal 204 sealed in the resin package 202.

The two terminals 203 and 204 include metal plates formed in a predetermined shape. The anode terminal 203 includes the island 205 and the terminal part 206. The island 205 has a rectangular shape including the two sides 203a and 203b parallel to each other in the X direction and the two sides 203c and 203d parallel to each other in the Y direction in plan view. The terminal part 206 linearly extends in the −X direction from the position closer to the −Y side end of the one side 203c of the island 205 and has a rectangular shape elongated in the X direction in plan view.

The cathode terminal 204 has a shape similar to the terminal part 206 of the anode terminal 203 in plan view, and the cathode terminal 204 is arranged at an interval from the terminal part 206 of the anode terminal 203 in the +Y direction. The +X side end of the cathode terminal 204 is arranged at an interval from the side 203c of the island 205 in the −X direction.

The fourth semiconductor apparatus 1C is mounted on the center part of the island 205 of the anode terminal 203 through flip-chip bonding. Specifically, the fourth semiconductor apparatus 1C is vertically inverted, and the anode electrode 39 of the fourth semiconductor apparatus 1C is connected to the upper surface of the island 205.

The cathode electrode 36 of the fourth semiconductor apparatus 1C is connected to the +X side part of the cathode terminal 204 in the length direction through the bonding wire 209.

The resin package 202 includes the main portion 202a in a cuboid shape, and the thin portion 202b arranged on the +X side of the main portion 202a and thinner than the main portion 202a. The bottom surface of the main portion 202a and the bottom surface of the thin portion 202b are flush with each other. The step portion 202c is formed between the upper surface of the thin portion 202b and the upper surface of the main portion 202a.

The main portion 202a seals the fourth semiconductor apparatus 1C, the part of the island 205 excluding the +X direction end, the base end of the terminal part 206, the +X side part of the cathode terminal 204 in the length direction, and the bonding wire 209. The thin portion 202b seals the +X direction end of the island 205.

The front end of the terminal part 206 protrudes in the −X direction from the end surface of the main portion 202a on the −X side. The −X side part of the cathode terminal 204 in the length direction protrudes in the −X direction from the end surface of the main portion 202a on the −X side.

The through hole 210 penetrating the thin portion 202b and the +X side end of the island 205 in the vertical direction is formed near the center of the thin portion 202b in plan view.

In the fourth semiconductor apparatus 1C, heat is easily generated at the boundary of the anode electrode 39 and the first main surface 34a of the drift layer 34. In the semiconductor package 201B, the anode electrode 39 is connected to the island 205 of the anode terminal 203, and the heat generated at the boundary of the anode electrode 39 and the first main surface 34a of the drift layer 34 can be easily released.

Although the embodiment of the present disclosure has been described, the present disclosure can also be carried out in other modes. For example, although the trenches 5 and 35 are formed in circular shapes in plan view in the first semiconductor apparatus 1 and the third semiconductor apparatus 1B, the trenches 5 and 35 may be formed in shapes other than the circular shapes, such as elliptical shapes and polygonal shapes. The sizes of the trenches 5 and 35 can also be set to any size.

Although the plurality of trenches 5 and 35 are arranged in grid patterns, such as matrix patterns and staggered patterns, in plan view in the second semiconductor apparatus 1A and the fourth semiconductor apparatus 1C, the plurality of trenches 5 and 35 may not be arranged in the grid patterns. The cross-sectional shapes and the sizes of the trenches 5 and 35 can be set as desired.

In the second semiconductor apparatus 1A and the fourth semiconductor apparatus 1C, although the plurality of trenches 5 and 35 are formed on substantially the entire second semiconductor apparatus 1A and fourth semiconductor apparatus 1C in plan view, the regions for forming the plurality of trenches 5 and 35 can be set as desired. For example, the plurality of trenches 5 and 35 may be formed in only regions at center parts of the semiconductor apparatuses 1A and 1C or may be formed in only regions at peripheries in plan view.

Although the anode electrodes 14 and 39 have two-layer structures in the first to fourth semiconductor apparatuses 1 to 1C, the anode electrodes 14 and 39 may have one-layer structures or structures with three or more layers, for example. Appropriate materials can be properly selected and used for the materials of the Schottky metal 15 (inside metal 40) and the electrode metal 16 (outside metal 41). The thicknesses of the Schottky metal 15 (inside metal 40) and the electrode metal 16 (outside metal 41) are examples, and appropriate values can be properly selected and used. Although the plane shapes of the anode electrodes 14 and 39 are rectangular shapes, the plane shapes may be shapes other than the rectangular shapes, such as circular shapes, elliptical shapes, and polygonal shapes.

Although the cathode electrodes 6 and 36 have two-layer structures in the first to fourth semiconductor apparatuses 1 to 1C, the cathode electrodes 6 and 36 may have one-layer structures or structures with three or more layers. Appropriate materials can be properly selected and used for the materials of the ohmic metal 7 (inside metal 37) and the electrode metal 8 (outside metal 38). The thicknesses of the ohmic metal 7 (inside metal 37) and the electrode metal 8 (outside metal 38) are examples, and appropriate values can be properly selected and used.

Although the buffer layers 3 and 33 are AlN layers in the first to fourth semiconductor apparatuses 1 to 1C, the buffer layers 3 and 33 may be AlAs layers, cubic AlN layers, C (diamond) layers, for example.

The following illustrates examples of the features extracted from the specification and the drawings. Although the alphabets, the numbers, for example, in parentheses represent corresponding constituent elements, for example, in the embodiment, the representation is not intended to limit the scope of the clauses to the embodiment.

### [A1]

A semiconductor package including:
a silicon substrate (2, 32) including a first main surface (2a, 32a) and a second main surface (2b, 32b);
a drift layer (4, 34) arranged on the first main surface (2a, 32a) of the silicon substrate (2, 32) and including a gallium semiconductor layer;
a buffer layer (3, 33) placed between the silicon substrate (2, 32) and the drift layer (4, 34);
an anode electrode (14, 39) that comes into contact with a first surface (4a, 34a) of the drift layer (4, 34), the first surface (4a, 34a) being a surface on a side opposite the buffer layer (3, 33);
a trench (5, 35) formed by digging the silicon substrate (2, 32) from the second main surface (2b, 32b) of the silicon substrate (2, 32) toward a second surface (4b, 34b) of the drift layer (4, 34), the second surface (4b, 34b) being a surface on a side opposite the first surface (4a, 34a), the trench (5, 35) penetrating the silicon substrate (2, 32) and the buffer layer (3, 33) and reaching the second surface (4b, 34b) of the drift layer (4, 34);
a semiconductor apparatus (1 to 1C) formed on an inner surface of the trench (5, 35) and including a cathode electrode (6, 36) that comes into contact with the second surface (4b, 34b) of the drift layer (4, 34);
an anode terminal (103, 203) on which the semiconductor apparatus (1 to 1C) is mounted through flip-chip bonding, the anode terminal (103, 203) being electrically connected to the anode electrode (14, 39);
a cathode terminal (104, 204) electrically connected to the cathode electrode (6, 36) of the semiconductor apparatus (1 to 1C) through a bonding wire (109, 209); and
a sealing resin (102, 202) for sealing the semiconductor apparatus (1 to 1C), the anode terminal (103, 203), and the cathode electrode (6, 36).

### [A2]

The semiconductor package according to [A1], in which
the first main surface (2a, 32a) is a (111) plane of the silicon substrate (2, 32).

### [A3]

The semiconductor package according to [A1] or [A2], in which
the gallium semiconductor layer contains gallium nitride or gallium oxide.

### [A4]

The semiconductor package according to [A3], in which
the gallium semiconductor layer includes an (Inₓ₁Ga₁₋ₓ)₂O₃ (0≤x1<1) layer, an (Alₓ₂Ga₁₋ₓ₂)₂O₃ (0≤x2<1) layer, a Scₓ₃Ga₁₋ₓ₃N (0≤x3<1) layer, a Tlₓ₄Ga₁₋ₓ₄N (0≤x4<1) layer, or an Alₓ₅Ga₁₋ₓ₅N (0≤x5<1) layer.

### [A5]

The semiconductor package according to any one of [A1] to [A4], in which
the buffer layer (3, 33) includes an aluminum nitride layer.

### [A6]

The semiconductor package according to any one of [A1] to [A5], in which
only one trench (5, 35) is formed.

### [A7]

The semiconductor package according to any one of [A1] to [A5], in which
a plurality of trenches (5, 35) are formed.

### [A8]

The semiconductor package according to any one of [A1] to [A7], in which
the anode electrode (14) includes a Schottky metal (15) that comes into Schottky contact with the first surface (4a) of the drift layer (4).

### [A9]

The semiconductor package according to any one of [A1] to [A8], in which
the cathode electrode (6) includes an ohmic metal (7) formed on an inner surface of the trench (5) and coming into ohmic contact with the second surface (4b) of the drift layer (4).

### [A10]

The semiconductor package according to any one of [A1] to [A9], in which
the semiconductor apparatus (1, 1A) is a Schottky barrier diode.

### [A11]

The semiconductor package according to [A10], in which
the drift layer (4) includes
   a first drift layer (21) formed on the first main surface (2a) and including a gallium semiconductor doped with n-type impurities, and
   a second drift layer (22) formed on a surface of the first drift layer (21) on a side opposite the silicon substrate (2) and including an undoped gallium semiconductor.

### [A12]

The semiconductor package according to [A11], in which
the n-type impurities contain silicon or tin.

### [A13]

The semiconductor package according to any one of any one of [A1] to [A7], in which
the semiconductor apparatus is a positive intrinsic negative diode.

### [A14]

The semiconductor package according to [A13], in which
the drift layer (34) includes
   a first drift layer (51) formed on the first main surface (32a) and including a gallium semiconductor doped with n-type impurities,
   a second drift layer (52) formed on a surface of the first drift layer (51) on a side opposite the silicon substrate (32) and including an undoped gallium semiconductor, and
   a third drift layer (53) formed on a surface of the second drift layer (52) on a side opposite the silicon substrate (32) and including a gallium semiconductor doped with p-type impurities.

### [A15]

The semiconductor package according to [A14], in which
the n-type impurities contain silicon or tin, and
the p-type impurities contain manganese.

Although the embodiment of the present disclosure has been described in detail, the embodiment is just a specific example used for clarifying the technical content of the present disclosure. The interpretation of the present disclosure should not be limited to the specific example, and the scope of the present disclosure is limited only by the attached claims.

What is claimed is:

1. A semiconductor package comprising:
a silicon substrate including a first main surface and a second main surface;
a drift layer arranged on the first main surface of the silicon substrate and including a gallium semiconductor layer;
a buffer layer placed between the silicon substrate and the drift layer;
an anode electrode that comes into contact with a first surface of the drift layer, the first surface being a surface on a side opposite the buffer layer;
a trench formed by digging the silicon substrate from the second main surface of the silicon substrate toward a second surface of the drift layer, the second surface being a surface on a side opposite the first surface, the trench penetrating the silicon substrate and the buffer layer and reaching the second surface of the drift layer;
a semiconductor apparatus formed on an inner surface of the trench and including a cathode electrode that comes into contact with the second surface of the drift layer;
an anode terminal on which the semiconductor apparatus is mounted through flip-chip bonding, the anode terminal being electrically connected to the anode electrode;
a cathode terminal electrically connected to the cathode electrode of the semiconductor apparatus through a bonding wire; and
a sealing resin for sealing the semiconductor apparatus, the anode terminal, and the cathode electrode.

2. The semiconductor package according to claim 1, wherein
the first main surface is a (111) plane of the silicon substrate.

3. The semiconductor package according to claim 1, wherein
the gallium semiconductor layer contains gallium nitride or gallium oxide Ga₂O₃.

4. The semiconductor package according to claim 3, wherein
the gallium semiconductor layer includes an (Inₓ₁Ga₁₋ₓ)₂O₃ (0≤x1<1) layer, an (Alₓ₂Ga₁₋ₓ₂)₂O₃ (0≤x2<1) layer, a Scₓ₃Ga₁₋ₓ₃N (0≤x3<1) layer, a Tlₓ₄Ga₁₋ₓ₄N (0≤x4<1) layer, or an Alₓ₅Ga₁₋ₓ₅N (0≤x5<1) layer.

5. The semiconductor package according to claim 1, wherein
the buffer layer includes an aluminum nitride layer.

6. The semiconductor package according to claim 1, wherein
only one trench is formed.

7. The semiconductor package according to claim 1, wherein
a plurality of trenches are formed.

8. The semiconductor package according to claim 1, wherein
the anode electrode includes a Schottky metal that comes into Schottky contact with the first surface of the drift layer.

9. The semiconductor package according to claim 1, wherein
the cathode electrode includes an ohmic metal formed on an inner surface of the trench and coming into ohmic contact with the second surface of the drift layer.

10. The semiconductor package according to claim 1, wherein
the semiconductor apparatus is a Schottky barrier diode.

11. The semiconductor package according to claim 10, wherein
the drift layer includes
a first drift layer formed on the first main surface and including a gallium semiconductor doped with n-type impurities, and
a second drift layer formed on a surface of the first drift layer on a side opposite the silicon substrate and including an undoped gallium semiconductor.

12. The semiconductor package according to claim 11, wherein
the n-type impurities contain silicon or tin.

13. The semiconductor package according to claim 1, wherein
the semiconductor apparatus is a positive intrinsic negative diode.

14. The semiconductor package according to claim 13, wherein
the drift layer includes
a first drift layer formed on the first main surface and including a gallium semiconductor doped with n-type impurities,
a second drift layer formed on a surface of the first drift layer on a side opposite the silicon substrate and including an undoped gallium semiconductor, and
a third drift layer formed on a surface of the second drift layer on a side opposite the silicon substrate and including a gallium semiconductor doped with p-type impurities.

15. The semiconductor package according to claim 14, wherein
the n-type impurities contain silicon or tin, and
the p-type impurities contain manganese.
